(19) United States
(12) Patent Application Publication
(10) Pub. No.: US 2023/0377828 A1
(43) Pub. Date: Nov. 23, 2023

(54) ELECTRON SOURCE, PLASMA SOURCE AND SWITCH DEVICE

(71) Applicants: KABUSHIKI KAISHA TOSHIBA, Tokyo (JP); TOSHIBA ENERGY SYSTEMS & SOLUTIONS CORPORATION, Kawasaki-shi Kanagawa (JP)

(72) Inventors: Hisao MIYAZAKI, Yokohama Kanagawa (JP); Hisashi YOSHIDA, Kawasaki Kanagawa (JP); Shigeya KIMURA, Yokohama Kanagawa (JP)

(73) Assignees: KABUSHIKI KAISHA TOSHIBA, Tokyo (JP); TOSHIBA ENERGY SYSTEMS & SOLUTIONS CORPORATION, Kawasaki-shi Kanagawa (JP)

(21) Appl. No.: 18/168,167

(22) Filed: Feb. 13, 2023

(30) Foreign Application Priority Data
May 17, 2022 (JP) 2022-080572

(51) Int. Cl. H01J 37/077; H01J 37/32

(52) U.S. Cl. CPC H01J 37/077; H01J 37/3244; H01J 2237/06366

(57) ABSTRACT

According to one embodiment, an electron source includes a base body and a first cathode layer. The first cathode layer includes a first diamond layer including a plurality of first polycrystalline diamonds, and a first member including a first element. At least a part of the first diamond layer is located between the base body and the first member. The first element includes at least one selected from the group consisting of Pd, Ni, Co, W, Mo, Ir and Ru.

### CROSS-REFERENCE TO RELATED APPLICATIONS

This application is based upon and claims the benefit of priority from Japanese Patent Application No. 2022-080572, filed on May 17, 2022; the entire contents of which are incorporated herein by reference.

### FIELD

Embodiments described herein relate generally to an electron source, a plasma source and a switching device.

### BACKGROUND

For example, a plasma is formed by an electron source.

There are switches using plasma. A highly efficient electron source is desired.

### BRIEF DESCRIPTION OF THE DRAWINGS

FIG. 1 is a schematic cross-sectional view illustrating an electron source according to a first embodiment;

FIG. 2 is an electron micrograph image illustrating the electron source according to the first embodiment;

FIG. 3 is a schematic cross-sectional view illustrating an electron source according to the first embodiment;

FIG. 4 is a graph illustrating the characteristics of the electron source according to the first embodiment;

FIG. 5 is a schematic cross-sectional view illustrating an electron source according to the first embodiment;

FIG. 6 is a schematic cross-sectional view illustrating a part of the electron source according to the first embodiment;

FIG. 7 is a schematic cross-sectional view illustrating an electron source according to the first embodiment;

FIG. 8A and FIG. 8B are schematic cross-sectional views illustrating the electron source according to the first embodiment;

FIG. 9A and FIG. 9B are schematic cross-sectional views illustrating the plasma source according to a second embodiment;

FIG. 10 is a schematic diagram illustrating the operation of the plasma source according to the second embodiment;

FIG. 11 is a schematic cross-sectional view illustrating the plasma source according to the second embodiment;

FIG. 12 is a schematic cross-sectional view illustrating a plasma source according to a third embodiment;

FIG. 13 is a schematic cross-sectional view illustrating the plasma source according to the third embodiment; and

FIG. 14 is a schematic cross-sectional view illustrating a switch device according to a fourth embodiment.

### DETAILED DESCRIPTION

According to one embodiment, an electron source includes a base body and a first cathode layer. The first cathode layer includes a first diamond layer including a plurality of first polycrystalline diamonds, and a first member including a first element. At least a part of the first diamond layer is located between the base body and the first member. The first element includes at least one selected from the group consisting of Pd, Ni, Co, W, Mo, Ir and Ru.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

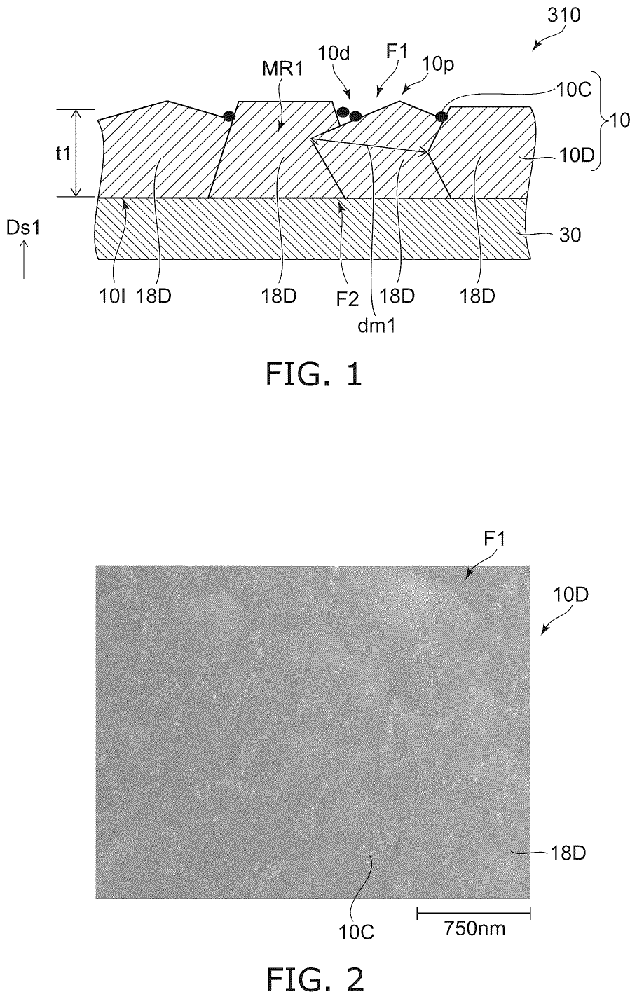

FIG. 1 is a schematic cross-sectional view illustrating an electron source according to the first embodiment.

As shown in FIG. 1, the electron source 310 according to the embodiment includes a base body 30 and a first cathode layer 10. The first cathode layer 10 is supported by the base body 30.

The first cathode layer 10 includes a first diamond layer 10D and a first member 10C. The first diamond layer 10D includes a plurality of first polycrystalline diamonds 18D. The first member 10C includes a first element.

The first element includes at least one selected from the group consisting of Pd, Ni, Co, W, Mo, Ir and Ru. For example, the first member 10C may include a plurality of grains including the first element. The first member 10C may be, for example, a grain including Pt, a grain including Mo, or the like. At least a part of the first member 10C may be in the form of a mesh or a film.

At least a part of the first diamond layer 10D is located between the base body 30 and the first member 10C.

The base body 30 includes, for example, at least one selected from the group consisting of molybdenum, tungsten, diamond, silicon, silicon carbide and gallium nitride. The base body 30 may be, for example, a substrate. The base body 30 may be conductive. The base body 30 may include crystals. For example, the first cathode layer 10 may be formed on the base body 30 by crystal growth. For example, the first cathode layer 10 is formed by epitaxial growth. Higher quality first cathode layer 10 is obtained. The base body 30 may be a single crystal substrate. When the base body 30 is a single crystal substrate, high crystallinity can be obtained in the first cathode layer 10. This results in electron emission with high efficiency. When the base body 30 is a single crystal substrate, the plane orientation of the crystal of the first cathode layer 10 can be controlled by the plane orientation of the substrate. For example, electron emission with high efficiency can be obtained.

In the embodiment, the first member 10C including the first element is provided on the surface of the first diamond layer 10D. As a result, it was found that high emission efficiency can be stably obtained.

In the embodiment, electrons are emitted from the first cathode layer 10. By the first cathode layer 10 including diamond, electrons are emitted stably with higher efficiency. The surface of diamond may be hydrogen terminated. By the hydrogen termination, electrons are emitted with higher efficiency.

In such a configuration, if the emission of electrons is continued, the ions existing in space may collide with the surface of the diamond and the hydrogen termination of the diamond may be partially destroyed. This generates unbonded bonds on the surface of the diamond. This may make it difficult to obtain high emission efficiency.

In the embodiment, the first member 10C including the first element is provided on the surface of the first diamond layer 10D. The first member 10C acts as a catalyst. For example, the first element of the first member 10C generates hydrogen radicals. Hydrogen radicals travel on the surface of the first diamond layer 10D and hydrogenate the unbonded bonds. As a result, the hydrogen termination can be stably maintained. According to the embodiment, a stable and highly efficient electron source can be provided.

In the embodiment, it is preferable that the first member 10C is provided on the surface of the first diamond layer 10D. For example, it is preferable that the first member 10C is not provided in the bulk of the first diamond layer 10D. If the first member 10C is provided in the bulk of the first diamond layer 10D, for example, the thermal conductivity or the like is lowered. Heat dissipation tends to decrease.

For example, as shown in FIG. 1, the first diamond layer 10D includes a first diamond face F1, a second diamond face F2, and a first intermediate region MR1. A direction from the base body 30 to the first diamond layer 10D is defined as a direction Ds1. The direction Ds1 is the stacking direction (or the growth direction). In the direction Ds1, the second diamond face F2 is located between the base body 30 and the first diamond face F1. The second diamond face F2 is a face facing the base body 30. The first diamond face F1 is a surface.

The first intermediate region MR1 is located between the first diamond face F1 and the second diamond face F2. The first intermediate region MR1 is, for example, a bulk region. In the embodiment, it is preferable that the first member 10C is not provided in the first intermediate region MR1. Alternatively, a concentration of the first member 10C at the first diamond face F1 is preferably higher than a concentration of the first member 10C in the first intermediate region MR1.

In the embodiment, it is preferable that the first member 10C is not provided on the second diamond face F2. Alternatively, the concentration of the first member 10C at the first diamond face F1 is preferably higher than a concentration of the first member 10C at the second diamond face F2.

As shown in FIG. 1, the first member 10C may be provided in a recess of the first diamond face F1. For example, the first diamond face F1 includes a depressing portion 10d and a protruding portion 10p. At least a part of the first member 10C is in the depressing portion 10d. For example, a concentration of the first member 10C in the depressing portion 10d is higher than a concentration of the first member 10C in the protruding portion 10p.

As shown in FIG. 1, each of the plurality of first polycrystalline diamonds 18D may grow from the surface of the base body 30. For example, each of the plurality of first polycrystalline diamonds 18D is fixed to the surface of the base body 30. For example, it is preferable that the plurality of first polycrystalline diamonds 18D have less overlap each other in the direction Ds1. This results in higher thermal conductivity. For example, when a diamond grain sintered body is used, the plurality of grains overlap each other. As a result, the thermal conductivity tends to be low.

For example, as shown in FIG. 1, a direction from one of the plurality of first polycrystalline diamonds 18 D to another one of the plurality of first polycrystalline diamonds 18 D is along a boundary 10I between the base body 30 and the first diamond layer 10D.

As shown in FIG. 1, an average diameter of the plurality of first polycrystalline diamonds 18D is defined as a diameter dm1. A thickness of the first diamond layer 10D in the direction Ds1 from the base body 30 to the first diamond layer 10D is defined as a thickness t1. The diameter dm1 is preferably, for example, ½ or more of the thickness t1. Overlapping of the plurality of first polycrystalline diamonds 18D is suppressed. The diameter dm1 may be, for example, 2 times or less the thickness t1.

In one example, “diameter” is the average of the constant directional diameters. The “diameter” may be any representative diameter. The representative diameter may be, for example, a triaxial diameter or an equivalent diameter. Information on the “diameter” may be obtained, for example, by measurement using the Small Angle X-ray Scattering Method (SAXS). Information on the “diameter” may be obtained, for example, from a surface image obtained by a scanning electron microscope or a transmission electron microscope. The “diameter” may be, for example, the average diameter of particles in a predetermined range within a predetermined range in the projected image of the surface image.

The average diameter dm1 of the plurality of first polycrystalline diamonds 18D is preferably not less than 200 nm and not more than 5000 nm. When the diameter dm1 is 200 nm or more, for example, a single layer of the plurality of first polycrystalline diamonds 18D can be easily obtained, and high thermal conductivity can be easily obtained. When the diameter dm1 is 5000 nm or less, for example, the voltage for emitting electrons can be easily lowered. For example, the first diamond layer 10D can be obtained with high productivity. The diameter dm1 may be 500 nm or less.

For example, the first member 10C is not substantially provided between the plurality of first polycrystalline diamonds. For example, a carbon included in one of the plurality of first polycrystalline diamonds 18D and a carbon included in another one of the plurality of first polycrystalline diamonds 18D may be bonded. A bond is a bond between carbons.

FIG. 2 is an electron micrograph image illustrating the electron source according to the first embodiment.

FIG. 2 is an electron micrograph image of the surface of the first diamond layer 10D (for example, the first diamond face F1). As shown in FIG. 2, the first member 10C is observed between the plurality of first polycrystalline diamonds 18D. In this example, the first member 10C is a Mo grain.

In the embodiment, for example, the first member 10C is attached to the surface of the first diamond layer 10D. The method of attachment is arbitrary. For example, the first cathode layer 10 according to the embodiment may be obtained by sputtering a member including the first element onto the first diamond layer 10D placed in the chamber. In one example, the diameter of the first member 10C (Mo grains or the like) is, for example, not less than 1 nm and not more than 50 nm.

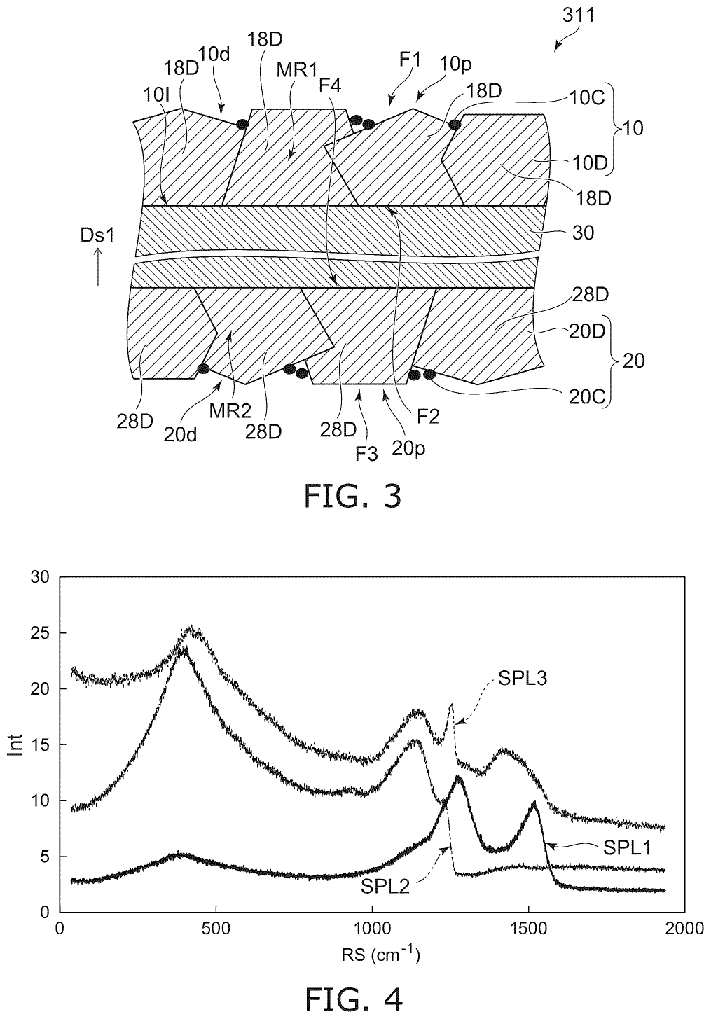

FIG. 3 is a schematic cross-sectional view illustrating an electron source according to the first embodiment.

As shown in FIG. 3, an electron source 311 according to the embodiment further includes a second cathode layer 20 in addition to the base body 30 and the first cathode layer 10. Except for this, the configuration of the electron source 311 may be the same as the configuration of the electron source 310.

The second cathode layer 20 includes a second diamond layer 20D and a second member 20C. The second diamond layer 20D includes a plurality of second polycrystalline diamonds 28D. The second member 20C includes a second element. The second element includes at least one selected from the group consisting of Pd, Ni, Co, W, Mo, Ir and Ru. The second element may be the same as the first element. The base body 30 is located between the second member 20C and the first member 10C. At least a portion of the second diamond layer 20D is located between the base body 30 and the second member 20C.

In the electron source 311, electrons are emitted from both the first cathode layer 10 and the second cathode layer 20. It is possible to increase the number of electrons emitted per unit area. Higher efficiency is obtained.

The configuration of the second cathode layer 20 may be the same as the configuration of the first cathode layer 10. For example, the second diamond layer 20D includes a third diamond face F3, a fourth diamond face F4, and a second intermediate region MR2. In the direction from the base body 30 to the second diamond layer 20D, the fourth diamond face F4 is located between the base body 30 and the third diamond face F3. The fourth diamond face F4 is a face facing the base body 30. The third diamond face F3 is a surface.

The second intermediate region MR2 is located between the third diamond face F3 and the fourth diamond face F4. The second intermediate region MR2 is, for example, a bulk region. For example, it is preferable that the second member 20C is not provided in the second intermediate region MR2. Alternatively, a concentration of the second member 20C at the third diamond face F3 is preferably higher than a concentration of the second member 20C in the second intermediate region MR2.

For example, it is preferable that the second member 20C is not provided at the fourth diamond face F4. Alternatively, the concentration of the second member 20C on the third diamond face F3 is higher than at concentration of the second member 20C on the fourth diamond face F4.

For example, the third diamond face F3 includes a depressing portion 20d and a protruding portion 20p. At least a part of the second member 20C is in the depressing portion 20d. For example, a concentration of the second member 20C in the depressing portion 20d is higher than a concentration of the second member 20C in the protruding portion 20p.

Hereinafter, examples of the characteristics of the first diamond layer 10D will be described. In the following, examples of the characteristics of three types of samples having different qualities will be described. In the first sample SPL1, the plurality of first polycrystalline diamonds 18D are relatively low quality p-type diamonds. In the second sample SPL2, the plurality of first polycrystalline diamonds 18D are relatively high quality p-type diamonds. In the third sample SPL3, the plurality of first polycrystalline diamonds 18D are high quality p-type diamonds.

In the first sample SPL1, the current that shifts from glow discharge to arc discharge is small. On the other hand, in the second sample SPL2 and the third sample SPL3, the current that shifts from the glow discharge to the arc discharge is large. Stable operation can be easily obtained in the second sample SPL2 and the third sample SPL3.

An example of the analysis results of these samples will be described.

FIG. 4 is a graph illustrating the characteristics of the electron source according to the first embodiment.

FIG. 4 illustrates the measurement results of Raman spectra for the first sample SPL1, the second sample SPL2, and the third sample SPL3. The horizontal axis of FIG. 4 is Raman shift RS. The vertical axis is the signal intensity Int (relative value).

In FIG. 4, the Raman shift RS of about 440 cm⁻¹ and the Raman shift RS of about 1205 cm⁻¹ correspond to B-doped diamond. The Raman shift RS of about 1305 cm⁻¹ corresponds to intrinsic diamond. Raman shift RS of about 1350 cm⁻¹ corresponds to disturbed spa-bonded carbon. Raman shift RS of about 1570 cm⁻¹ corresponds to sp²-bonded carbon.

As shown in FIG. 4, in the Raman spectrum of the first sample SPL1, the Raman shift RS has a high intensity Int at about 1350 cm⁻¹, and the Raman shift RS has a high intensity Int at about 1570 cm⁻¹. This indicates that the proportion of sp²-bonded carbon is high in the first sample SPL1.

In the second sample SPL2 and the third sample SPL3, their intensity Int is low. This indicates that the proportion of sp³-bonded carbon is high in the second sample SPL2 and the third sample SPL3.

In the embodiment, in the Raman spectrum of the first cathode layer 10, the intensity Int in the Raman shift RS of 440 cm⁻¹ is preferably higher than the intensity Int in the Raman shift RS of 1350 cm⁻¹, and higher than the intensity Int in the Raman shift RS of 1570 cm⁻¹.

In the first cathode layer 10, the intensity Int in the Raman shift RS of 1205 cm⁻¹ is preferably higher than the intensity Int in the Raman shift RS of 1350 cm⁻¹ and higher than the intensity Int in the Raman shift RS of 1570 cm⁻¹.

With the above characteristics, for example, power consumption in discharging can be reduced. For example, glow discharge can be maintained up to high current densities. For example, the transition to arc discharge can be effectively suppressed.

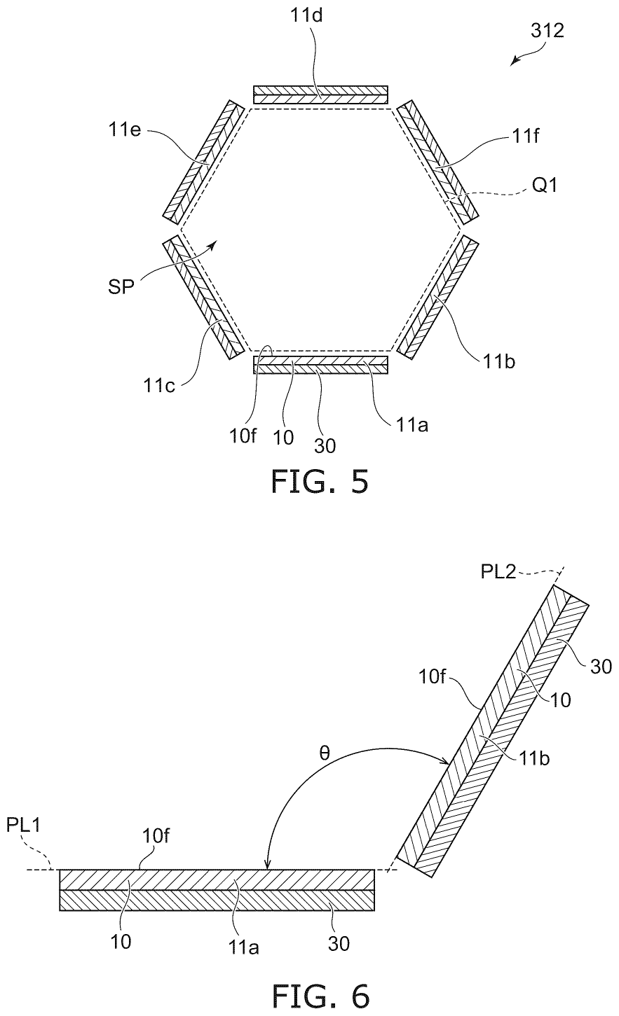

FIG. 5 is a schematic cross-sectional view illustrating an electron source according to the first embodiment.

As shown in FIG. 5, in the electron source 312 according to the embodiment, a plurality of first cathode layers 10 are provided. In this example, a plurality of base bodies 30 are provided. One of the plurality of first cathode layers 10 is provided on one of the plurality of base bodies 30. A plurality of first cathode layers 10 may be provided on one base body 30.

As shown in FIG. 5, the plurality of first cathode layers 10 are arranged along the plurality of sides of the polygon Q1. Each of the plurality of first cathode layers 10 includes a first face 10f. The first face 10f is a planar face facing the inside of the polygon Q1.

For example, the plurality of first cathode layers 10 include cathode layers 11a to 11f and the like. Each of the cathode layers 11a to 11f has a planar first face 10f. With such a configuration, electrons are efficiently emitted to the space SP surrounded by the plurality of first cathode layers 10.

FIG. 6 is a schematic cross-sectional view illustrating a part of the electron source according to the first embodiment.

FIG. 6 illustrates a part of FIG. 5. One of the plurality of first cathode layers 10 (e.g., cathode layer 11a) is next to another one of the plurality of first cathode layers 10 (e.g., cathode layer 11b). The angle between the first face 10f of the first cathode layer 10 (cathode layer 11a) and the first face 10f of the other one of the plurality of first cathode layers 10 (cathode layer 11b) is defined as angle θ. In the embodiments, the angle θ is preferably greater than 90 degrees. The angle θ may be, for example, 120 degrees or more. The angle θ corresponds to the angle between a plane PL1 including the first face 10f of the cathode layer 11a and a plane PL2 including the first face 10f of the cathode layer 11b. As the angle θ is large, the cross section of the space surrounded by the plurality of first cathode layers 10 becomes nearly circular.

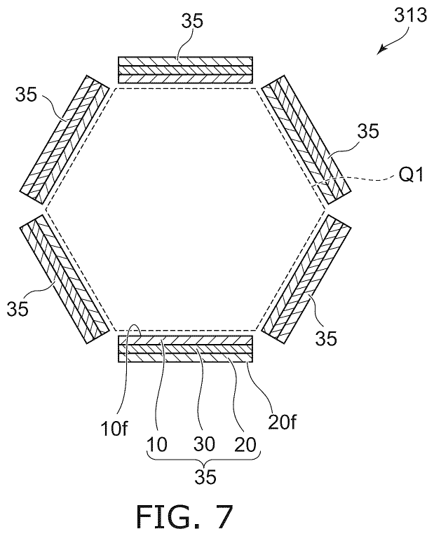

FIG. 7 is a schematic cross-sectional view illustrating an electron source according to the first embodiment.

As shown in FIG. 7, an electron source 313 according to the embodiment includes a plurality of stacked bodies 35. Each of the plurality of stacked bodies 35 includes the first cathode layer 10, the base body 30, and the second cathode layer 20. The base body 30 is located between the first cathode layer 10 and the second cathode layer 20. The configuration of the stacked body 35 may be, for example, the same as the configuration of the electron source 311 illustrated in FIG. 3.

As described above, the electron source 313 includes the plurality of second cathode layers 20. In the electron source 313, the plurality of first cathode layers 10 are provided. At least a part of the base body 30 is located between one of the plurality of first cathode layers 10 and one of the plurality of second cathode layers 20. The plurality of first cathode layers 10 are planar. The plurality of first cathode layers 10 are along the plurality of sides of a polygon Q1. Each of the plurality of first cathode layers 10 includes a planar first face 10f facing inward of the polygon Q1. Each of the plurality of second cathode layers includes a planar second face 20f facing the outside of the polygon Q1.

As described with respect to FIG. 3, one of the plurality of second cathode layers 20 includes the second diamond layer 20D and the second member 20C. The second diamond layer 20D includes the plurality of second polycrystalline diamonds 28D. The second member 20C includes the second element. The second element includes at least one selected from the group consisting of Pd, Ni, Co, W, Mo, Ir and Ru. The base body 30 is located between the second member 20C and the first member 10C. At least a part of the second diamond layer 20D is located between the base body 30 and the second member 20C.

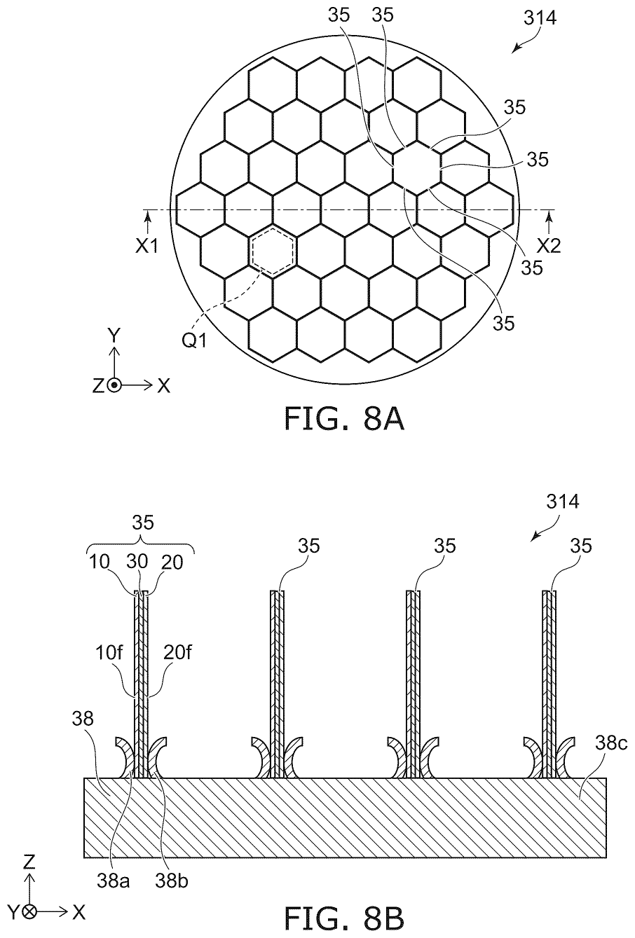

FIG. 8A and FIG. 8B are schematic cross-sectional views illustrating the electron source according to the first embodiment.

These figures illustrate the electron source 314 according to the embodiment. FIG. 8B is a cross-sectional view taken along the line X1-X2 of FIG. 8A. As shown in FIG. 8A, in the electron source 314, a plurality of polygons Q1 are provided along the X-Y plane. The Y-axis direction is perpendicular to the X-axis direction. A direction perpendicular to the X-axis direction and the Y-axis direction is defined as a Z-axis direction.

As shown in FIG. 8A, the plurality of stacked bodies 35 are along the plurality of sides of the polygon Q1. Multiple groups including such multiple stacked bodies 35 are arranged along the X-Y plane. FIG. 8A shows an example in which the polygon Q1 is a regular hexagon.

As shown in FIG. 8B, the electron source 314 may include a support portion 38. The support portion 38 supports the multiple stacked bodies 35. For example, the support portion 38 includes a first support member 38a and a second support member 38b. For example, one of the plurality of stacked bodies 35 is located between the first support member 38a and the second support member 38b.

The support portion 38 may include a third support member 38c. The third support member 38c supports the first support member 38a and the second support member 38b. The third support member 38c is a base. The first support member 38a and the second support member 38b are, for example, elastic members.

### Second Embodiment

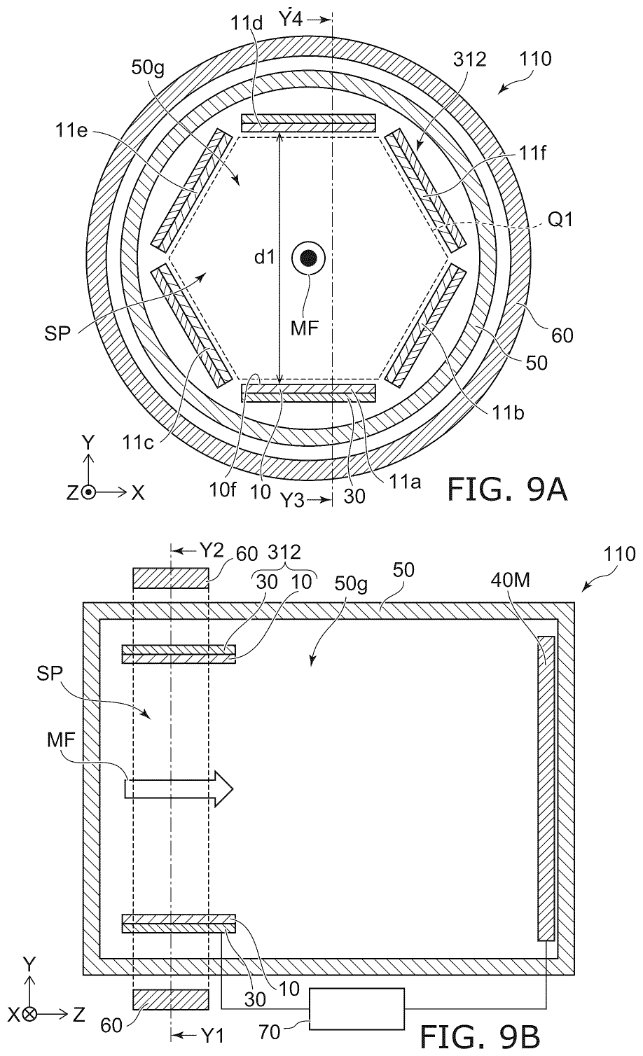

FIG. 9A and FIG. 9B are schematic cross-sectional views illustrating the plasma source according to a second embodiment.

FIG. 9A is a cross-sectional view taken along the line Y1-Y2 of FIG. 9B. FIG. 9B is a cross-sectional view taken along the line Y3-Y4 of FIG. 9A.

As shown in FIG. 9A and FIG. 9B, the plasma source 110 according to the embodiment includes a container 50, the electron source (electron source 312 in this example), and an anode member 40M. Any electron source according to the first embodiment may be used.

The container 50 is configured to store gas 50g. The gas 50g is stored in the space inside the container 50. The gas 50g includes, for example, at least one selected from the group consisting of argon, helium, hydrogen, and deuterium. The plasma source 110 may include gas 50g. When using the plasma source 110, the gas 50g may be introduced into the container 50. For example, the gas 50g may be introduced into the inside of the container 50 from an introduction port or the like provided in the container 50. The container 50 is configured to airtightly hold the space inside the container 50.

The electron source 312 is provided in the container 50. The anode member 40M is provided in the container 50. The anode member 40M is separated from the electron source 312.

As shown in FIG. 9B, a controller 70 may be provided. The controller 70 is configured to apply a voltage between the electron source 312 and the anode member 40M, for example.

As shown in FIG. 9A and FIG. 9B, the magnetic field application portion 60 may be provided. The plasma source 110 may include the magnetic field application portion 60. The magnetic field application portion 60 is configured to apply the magnetic field MF to the space SP surrounded by the plurality of first cathode layers 10. The magnetic field MF includes a component in a direction (for example, the Z-axis direction) that crosses the plane (X-Y plane) including the polygon Q1. For example, the magnetic field MF is along the Z-axis direction. The magnetic field application portion 60 may be, for example, a magnet (for example, a permanent magnet). The magnetic field application portion 60 may be, for example, an electromagnet. For example, the anode member 40M is separated from the electron source 312 in the Z-axis direction.

With such a magnetic field MF, the electron source 312 may function as a cross-field hollow cathode.

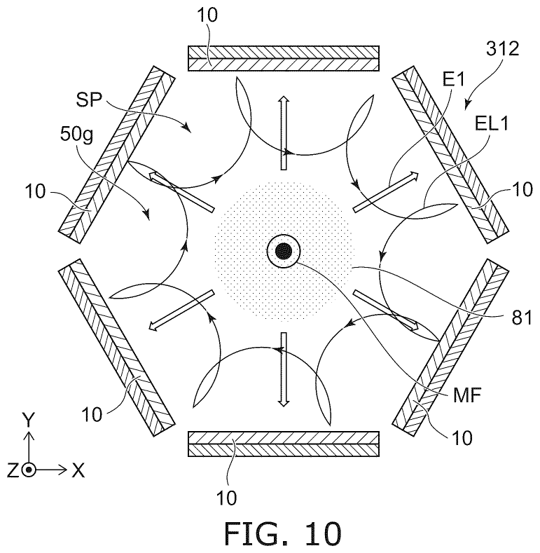

FIG. 10 is a schematic diagram illustrating the operation of the plasma source according to the second embodiment.

As shown in FIG. 10, the magnetic field MF is applied to the space SP surrounded by the cylindrical (or annular) electron source 312. The magnetic field MF is along the axial direction (Z-axis direction) of the cylinder. A negative glow 81 is formed in the center of the space SP. An electric field E1 is generated between the negative glow 81 and the electron source 312. The electron EL1 drifts while swirling in the cylinder due to the magnetic field MF and the electric field E1. The electron EL1 repeatedly collides with particles (molecules and the like) of the gas 50g. This promotes ionization. This gives a high density plasma.

In the embodiment, the angle of the apex of the polygon Q1 of the plurality of first cathode layers 10 is preferably more than 90 degrees. Thereby, it is possible to suppress the above-mentioned drift of the electron EL1 from being hindered. The polygon Q1 may be, for example, a regular polygon.

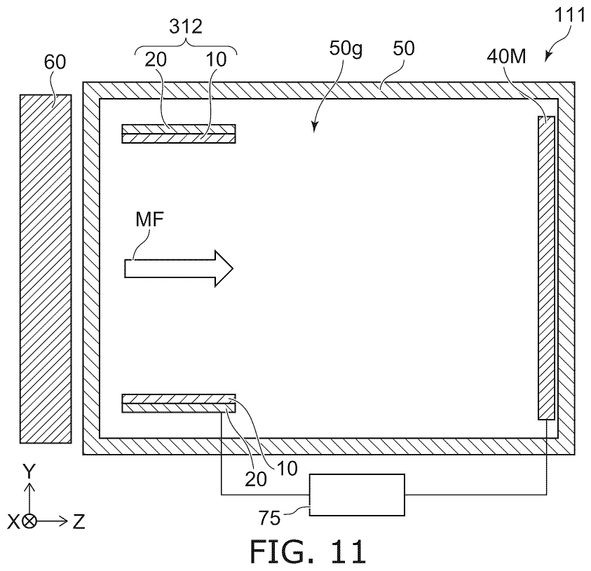

FIG. 11 is a schematic cross-sectional view illustrating the plasma source according to the second embodiment.

As shown in FIG. 11, in a plasma source 111 according to the embodiment, the magnetic field application portion 60 is in the X-Y plane and does not overlap the electron source 312. For example, in the Z-axis direction, the electron source 312 may be between the container 50 and the anode member 40M. At least a part of the magnetic field application portion 60 need not overlap the container 50 in the X-Y plane.

### Third Embodiment

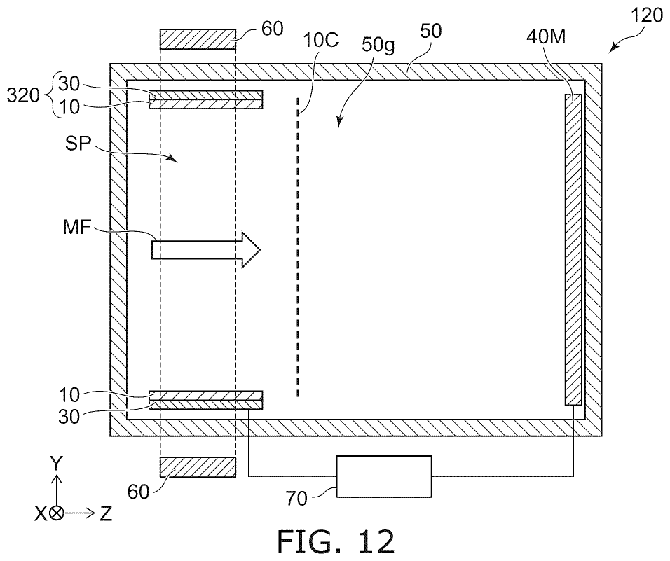

FIG. 12 is a schematic cross-sectional view illustrating a plasma source according to a third embodiment.

As shown in FIG. 12, a plasma source 120 according to the embodiment includes the container 50, the electron source 320, the anode member 40M, and a first member 10C. The container 50 is configured to store the gas 50gs. The electron source 320, the anode member 40M, and the first member 10C are provided in the container 50.

The electron source 320 includes a base body 30 and the first cathode layer 10 supported by the base body 30. The first cathode layer 10 includes the plurality of first polycrystalline diamonds 18D (see FIG. 1). In the third embodiment, the first cathode layer 10 need not include the first member 10C.

The first member 10C includes the first element. The first element includes at least one selected from the group consisting of Pd, Ni, Co, W, Mo, Ir and Ru. In this example, the first member 10C is located between the electron source 320 and the anode member 40M. The first member 10C is, for example, a grid.

In the plasma source 120, the first element included in the first member 10C adheres to the first cathode layer 10 by operating the plasma source 120. The first element adheres to the surface of the plurality of first polycrystalline diamonds 18D. For example, the first element of the first member 10C generates hydrogen radicals. Hydrogen radicals travel on the surface of the first diamond layer 10D and hydrogenate the unbonded bonds. As a result, the hydrogen termination can be stably maintained. In the third embodiment, a stable and highly efficient plasma source can be provided. In the plasma source 120, the first cathode layer 10 may include the first member 10C.

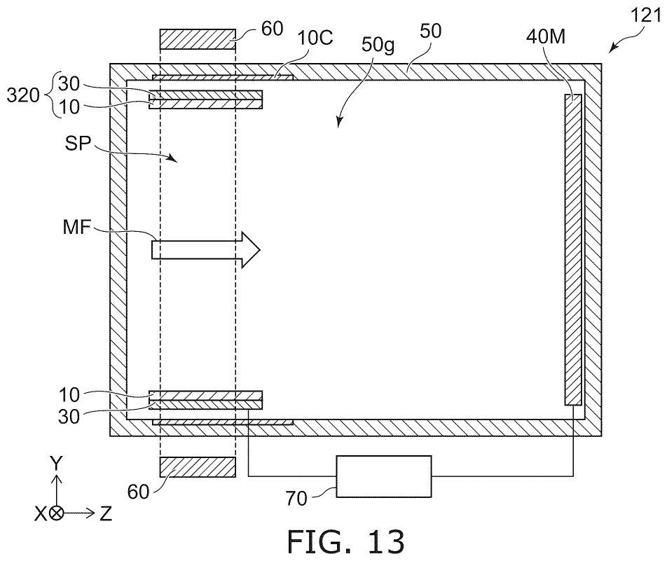

FIG. 13 is a schematic cross-sectional view illustrating the 30 plasma source according to the third embodiment.

As shown in FIG. 13, the plasma source 121 according to the embodiment includes the container 50, the electron source 320, and the anode member 40M. The container 50 is configured to store the gas 50g. The electron source 320 and the anode member 40M are provided in the container 50.

The electron source 320 includes the base body 30 and the first cathode layer 10 supported by the base body 30. The first cathode layer 10 includes the plurality of first polycrystalline diamonds 18D. In the third embodiment, the first cathode layer 10 need not include the first member 10C.

As shown in FIG. 13, at least a part of the inner face of the container 50 includes the first member 10C. The first member 10C includes the first element. The first element includes at least one selected from the group consisting of Pd, Ni, Co, W, Mo, Ir and Ru.

In the plasma source 121, the first element included in the first member 10C adheres to the first cathode layer 10 by operating the plasma source 121 as well. As a result, the hydrogen termination can be stably maintained. A stable and highly efficient plasma source can be provided. In the plasma source 121, the first cathode layer 10 may include the first member 10C.

### Fourth Embodiment

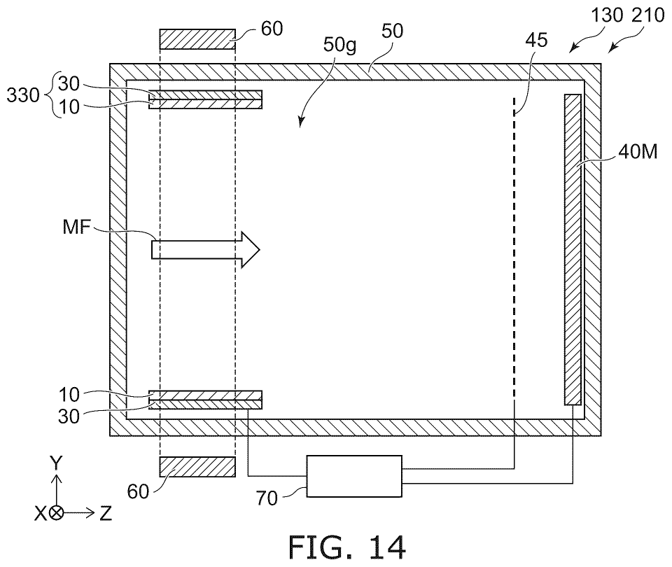

FIG. 14 is a schematic cross-sectional view illustrating a switch device according to a fourth embodiment.

As shown in FIG. 14, a switch device 210 according to the embodiment includes the plasma source 130 and a control conductive portion 45. As the plasma source 130, any plasma source according to the second embodiment or the third embodiment may be applied. The control conductive portion 45 is provided in the container 50. The control conductive portion 45 is connected to, for example, the controller 70. The potential of the control conductive portion 45 is controlled by the controller 70. Thereby, the current flowing between the electron source (electron source 330 in this example) and the anode member 40M can be controlled. According to the fourth embodiment, a stable and highly efficient switch device can be provided. The control conductive portion 45 may include the first member 10C. Hydrogen termination can be maintained stably.

The embodiment may include the following configuration (for example, technical proposals).

Configuration 1

An electron source, comprising:
a base body; and
a first cathode layer,
the first cathode layer including
   a first diamond layer including a plurality of first polycrystalline diamonds, and
   a first member including a first element,
at least a part of the first diamond layer being located between the base body and the first member, and
the first element including at least one selected from the group consisting of Pd, Ni, Co, W, Mo, Ir and Ru.

Configuration 2

The electron source according to Configuration 1, wherein
the first diamond layer includes a first diamond face, a second diamond face and a first intermediate region,
the second diamond face is located between the base body and the first diamond face in a direction from the base body to the first diamond layer,
the first intermediate region is located between the first diamond face and the second diamond face, and
the first member is not provided in the first intermediate region, or a concentration of the first member at the first diamond face is higher than a concentration of the first member in the first intermediate region.

Configuration 3

The electron source according to Configuration 1, wherein
the first diamond layer includes a first diamond face and a second diamond face,
the second diamond face is located between the base body and the first diamond face in a direction from the base body to the first diamond layer, and
the first member is not provided at the second diamond face, or a concentration of the first member at the first diamond face is higher than a concentration of the first member at the second diamond face.

Configuration 4

The electron source according to Configuration 1, wherein
the first diamond layer includes a first diamond face and a second diamond face,
the second diamond face is located between the base body and the first diamond face in a direction from the base body to the first diamond layer,
the first diamond face includes a depressing portion and a protruding portion, and
at least a part of the first member is in the depressing portion.

Configuration 5

The electron source according to Configuration 4, wherein a concentration of the first member in the depressing portion is higher than a concentration of the first member in the protruding portion.

Configuration 6

The electron source according to any one of Configurations 1 to 5, wherein the first member includes a plurality of grains including the first element.

Configuration 7

The electron source according to any one of Configurations 1 to 6, wherein a direction from one of the plurality of first polycrystalline diamonds to another one of the plurality of first polycrystalline diamonds is along a boundary between the base body and the first diamond layer.

Configuration 8

The electron source according to any one of Configurations 1 to 7, wherein an average diameter of the plurality of first polycrystalline diamonds is ½ or more of a thickness of the first diamond layer in a direction from the base body to the first diamond layer.

Configuration 9

The electron source according to any one of Configurations 1 to 8, wherein an average diameter of the plurality of first polycrystalline diamonds is not less than 200 nm and not more than 5000 nm.

Configuration 10

The electron source according to any one of Configurations 1 to 9, wherein a carbon included in one of the plurality of first polycrystalline diamonds and a carbon included in another one of the plurality of first polycrystalline diamonds are bonded to each other.

Configuration 11

The electron source according to any one of Configurations 1 to 10, wherein
a plurality of the first cathode layers are provided,
the plurality of first cathode layers are arranged along a plurality of sides of a polygon, respectively, and
each of the plurality of first cathode layers includes a planar first face facing inward of the polygon.

Configuration 12

The electron source according to Configuration 11, wherein
one of the plurality of first cathode layers is adjacent to another one of the plurality of first cathode layers, and
an angle between the first face of the one of the plurality of the first cathode layer and the first face of the other one the plurality of first cathode layers exceeds 90 degrees.

Configuration 13

The source according to any one of Configurations 1 to 10, further comprising a second cathode layer,
the second cathode layer including:
   the second diamond layer including a plurality of second polycrystalline diamonds, and
   a second member including a second element,
the base body being located between the second member and the first member,
at least a part of the second diamond layer being located between the base body and the second member, and
the second element including at least one selected from the group consisting of Pd, Ni, Co, W, Mo, Ir and Ru.

Configuration 14

The electron source according to Configuration 13, wherein
the second diamond layer includes a third diamond face and a fourth diamond face,
the fourth diamond surface is located between the base body and the third diamond surface in a direction from the base body to the second diamond layer, and
the second member is not provided at the fourth diamond face, or a concentration of the second member at the third diamond surface is higher than a concentration of the second member at the fourth diamond surface.

Configuration 15

The electron source according to any one of Configurations 1 to 11, further comprising a plurality of second cathode layers,
a plurality of the first cathode layers being provided,
at least a part of the base body being located between one of the plurality of first cathode layers and one of the plurality of second cathode layers,
the plurality of first cathode layers being planar,
the plurality of first cathode layers being arranged along a plurality of sides of a polygon, respectively,
each of the plurality of first cathode layers including a planar first surface facing inward of the polygon,
each of the plurality of second cathode layers including a planar second surface facing the outside of the polygon,
the one of the plurality of second cathode layers including
   a second diamond layer including a plurality of second polycrystalline diamonds, and
   a second member including a second element,
the base body being provided between the second member and the first member,
at least a part of the second diamond layer being located between the base body and the second member, and
the second element including at least one selected from the group consisting of Pd, Ni, Co, W, Mo, Ir and Ru.

Configuration 16

The electron source according to any one of Configurations 1 to 15, wherein in Raman spectra of the plurality of first diamond layers, an intensity at Raman shift of 440 cm−1 is higher than an intensity at the Raman shift of 1350 cm−1 and higher than an intensity at the Raman shift of 1570 cm−1.

Configuration 17

A plasma source, comprising:
a container configured to store gas;
the electron source according to any one of Configurations 1 to 16, the electron source being provided in the container; and
an anode member provided in the container.

Configuration 18

A plasma source, comprising:
a container configured to store gas;
an electron source being provided in the container, the electron source including a base body and a first cathode layer supported by the base body, the first cathode layer including a plurality of first polycrystalline diamonds;
an anode member provided in the container; and
a first member provided in the container, the first member including a first element including at least one selected from the group consisting of Pd, Ni, Co, W, Mo, Ir and Ru.

Configuration 19

A plasma source, comprising:
a container configured to store gas;
an electron source being provided in the container, the electron source including a base body and a first cathode layer supported by the base body, the first cathode layer including a plurality of first polycrystalline diamonds; and
an anode member provided in the container,
at least a part of an inner face of the container including a first member, and
the first member including a first element including at least one selected from the group consisting of Pd, Ni, Co, W, Mo, Ir and Ru.

Configuration 20

A switch device, comprising:
the plasma source according to any one of Configurations 17 to 19; and
a control conductive portion provided in the container.

According to embodiments, it is possible to provide high efficiency electron sources, plasma sources, and switching devices.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in electron sources, plasma sources, and switching devices such as cathode layers, anode members, containers, magnetic field application portions, controllers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all electron sources, plasma sources, and switching devices practicable by an appropriate design modification by one skilled in the art based on the electron sources, the plasma sources, and the switching devices described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An electron source, comprising:
a base body; and
a first cathode layer,
the first cathode layer including
a first diamond layer including a plurality of first polycrystalline diamonds, and
a first member including a first element,
at least a part of the first diamond layer being located between the base body and the first member, and
the first element including at least one selected from the group consisting of Pd, Ni, Co, W, Mo, Ir and Ru.

2. The source according to claim 1, wherein
the first diamond layer includes a first diamond face, a second diamond face and a first intermediate region,
the second diamond face is located between the base body and the first diamond face in a direction from the base body to the first diamond layer,
the first intermediate region is located between the first diamond face and the second diamond face, and
the first member is not provided in the first intermediate region, or a concentration of the first member at the first diamond face is higher than a concentration of the first member in the first intermediate region.

3. The source according to claim 1, wherein
the first diamond layer includes a first diamond face and a second diamond face,
the second diamond face is located between the base body and the first diamond face in a direction from the base body to the first diamond layer, and
the first member is not provided at the second diamond face, or a concentration of the first member at the first diamond face is higher than a concentration of the first member at the second diamond face.

4. The source according to claim 1, wherein
the first diamond layer includes a first diamond face and a second diamond face,
the second diamond face is located between the base body and the first diamond face in a direction from the base body to the first diamond layer,
the first diamond face includes a depressing portion and a protruding portion, and
at least a part of the first member is in the depressing portion.

5. The source according to claim 4, wherein a concentration of the first member in the depressing portion is higher than a concentration of the first member in the protruding portion.

6. The source according to claim 1, wherein the first member includes a plurality of grains including the first element.

7. The source according to claim 1, wherein a direction from one of the plurality of first polycrystalline diamonds to another one of the plurality of first polycrystalline diamonds is along a boundary between the base body and the first diamond layer.

8. The source according to claim 1, wherein an average diameter of the plurality of first polycrystalline diamonds is ½ or more of a thickness of the first diamond layer in a direction from the base body to the first diamond layer.

9. The source according to claim 1, wherein an average diameter of the plurality of first polycrystalline diamonds is not less than 200 nm and not more than 5000 nm.

10. The source according to claim 1, wherein a carbon included in one of the plurality of first polycrystalline diamonds and a carbon included in another one of the plurality of first polycrystalline diamonds are bonded to each other.

11. The source according to claim 1, wherein
a plurality of the first cathode layers are provided,
the plurality of first cathode layers are arranged along a plurality of sides of a polygon, respectively, and
each of the plurality of first cathode layers includes a planar first face facing inward of the polygon.

12. The source according to claim 11, wherein
one of the plurality of first cathode layers is adjacent to another one of the plurality of first cathode layers, and
an angle between the first face of the one of the plurality of the first cathode layer and the first face of the other one the plurality of first cathode layers exceeds 90 degrees.

13. The source according to claim 1, further comprising a second cathode layer,
the second cathode layer including:
the second diamond layer including a plurality of second polycrystalline diamonds, and
a second member including a second element,
the base body being located between the second member and the first member,
at least a part of the second diamond layer being located between the base body and the second member, and
the second element including at least one selected from the group consisting of Pd, Ni, Co, W, Mo, Ir and Ru.

14. The source according to claim 13, wherein
the second diamond layer includes a third diamond face and a fourth diamond face,
the fourth diamond surface is located between the base body and the third diamond surface in a direction from the base body to the second diamond layer, and
the second member is not provided at the fourth diamond face, or a concentration of the second member at the third diamond surface is higher than a concentration of the second member at the fourth diamond surface.

15. The source according to claim 1, further comprising a plurality of second cathode layers,
a plurality of the first cathode layers being provided,
at least a part of the base body being located between one of the plurality of first cathode layers and one of the plurality of second cathode layers,
the plurality of first cathode layers being planar,
the plurality of first cathode layers being arranged along a plurality of sides of a polygon, respectively,
each of the plurality of first cathode layers including a planar first surface facing inward of the polygon,
each of the plurality of second cathode layers including a planar second surface facing the outside of the polygon,
the one of the plurality of second cathode layers including
a second diamond layer including a plurality of second polycrystalline diamonds, and
a second member including a second element,
the base body being provided between the second member and the first member,
at least a part of the second diamond layer being located between the base body and the second member, and
the second element including at least one selected from the group consisting of Pd, Ni, Co, W, Mo, Ir and Ru.

16. The source according to claim 1, wherein in Raman spectra of the plurality of first diamond layers, an intensity at Raman shift of 440 cm⁻¹ is higher than an intensity at the Raman shift of 1350 cm⁻¹ and higher than an intensity at the Raman shift of 1570 cm⁻¹.

17. A plasma source, comprising:
a container configured to store gas;
the electron source according to claim 1, the electron source being provided in the container; and
an anode member provided in the container.

18. A plasma source, comprising:
a container configured to store gas;
an electron source being provided in the container, the electron source including a base body and a first cathode layer supported by the base body, the first cathode layer including a plurality of first polycrystalline diamonds;
an anode member provided in the container; and
a first member provided in the container, the first member including a first element including at least one selected from the group consisting of Pd, Ni, Co, W, Mo, Ir and Ru.

19. A switch device, comprising:
the plasma source according to claim 17; and
a control conductive portion provided in the container.
